(19) United States
(12) Patent Application Publication
(10) Pub. No.: US 2004/0031958 A1
(43) Pub. Date: Feb. 19, 2004

(54) Fabrication method of graded organic junction

(75) Inventors: Chung-Chih Wu, Taipei (TW); Chieh-Wei Chen, Taipei (TW); Tung-Yi Cho, Taipei (TW); Tien-Yau Luh, Taipei (TW)

Correspondence Address: Johnson & Associates, P.C., 14625 Baltimore Avenue # 282, Laurel, MD, 20707, US

(73) Assignee: National Taiwan University

(21) Appl. No.: 10/434,231

(22) Filed: May 9, 2003

(30) Foreign Application Priority Data
Aug. 19, 2002 (TW) 091118651

(51) Int. Cl. H01L 35/24; H01L 51/00

(52) U.S. Cl. 257/40

(57) ABSTRACT

A fabrication method for graded organic junction by adding an interfacial fusing layer between two organic layers is disclosed. Said interfacial fusing layer has its glass transition temperature lower than the neighboring organic layers, and said fusing layer will cause smooth interdiffusion and mixing of neighboring layers to form a graded organic junction when annealing above its glass transition temperature Tg. The process of interdiffusion can be monitored with optical measurement device on real time basis. The light emitting diode (LED) component containing graded organic junction thus produced has higher luminescence efficiency and lower operation voltage in comparison with conventional components.

### BACKGROUND OF INVENTION

1. Field of the Invention

The invention relates to a fabrication method for graded organic junction, which more specifically can be applied to fabrication process for organic optoelectronic components with plural organic layers.

2. Description of Related Art

The organic optoelectronic components, such as organic light emitting components, organic light sensor components, solar cells, lasers and transistors, usually contain plural organic layers. During the fabrication process of the organic optoelectronic components, usually several organic layers of different properties need to be stacked to produce proper function of optoelectronic component. The properties of organic junction interface will usually affect the efficiency and life span of the optoelectronic component. For example, the first organic light emitting diode (OLED) was disclosed in J. Chem. Phys. 38, 2042 (1963) by Mr. Pope et al, in which approximately 1000 volt was applied on the two sides of anthracene crystal of ˜1 mm thick and light emission was observed. These early devices were not introduced in commercial market of flat panel display due to its high operation voltage. More advanced and practical OLED component structure and its fabrication method were disclosed by C. W. Tang and S. A. VanSlyke of Eastman Kodak company in Appl. Phys. Lett. 51, 913 (1987). The fabrication method adopted thermal vacuum deposition process to deposit thin films of amorphous organic materials in sequence onto a transparent glass substrate coated with a transparent ITO (Indium—Tin—Oxide) anode, followed by coating with a metal electrode (cathode) to produce the component. The OLED thus produced with such fabrication method reduced the operation voltage to approximately 10 volt and consequently became more practical in applications. The vacuum deposition process adopted in the fabrication method is more suitable for mass production of large area display. Further, such OLED has features of rapid response time, self-emissive and the low-temperature fabrication process, making it an important technology in the field of flat panel displays.

The typical OLED component structure of prior art was fabricated by depositing thin film of amorphous organic material having hole-transport and electron-transport characteristics sequentially onto an ITO-coated transparent glass substrate, and then followed by coating with a metal electrode (cathode). Because different organic materials were deposited sequentially to form the component and have unmatched energy levels and transport characteristics of different organic materials, abrupt hetero-junctions will be formed between different organic materials. Such abrupt hetero-junction may confine a high concentration of electrons and holes at neighborhood of the junction. Such higher electron and hole concentration in turn can enhance luminescence quantum efficiency of component. On the other hand, the abrupt hetero-junction may also hinder positive and negative carriers from injecting into its neighboring organic layers, causing a high concentration of space charges to accumulate at neighborhood of the junction, forming a local high electric field, consequently resulting in adverse effect on operation voltage and life span of components.

In order to solve the drawbacks of abrupt hetero-junction mentioned above, in disclosures made by V. -E. Choong et al in Appl. Phys. Lett. 75, 172 (1999), U.S. Pat. No. 6,194,089 and U.S. Pat. No. 5,925,980, the original separately and discretely formed thin films of electron-transport and hole-transport materials were replaced by co-deposition method to produce a single-layer component named bipolar transport layer device. As there was no abrupt hetero-junction within such component, therefore, its operation voltage was reduced and the life span of components was lengthened. Yet, luminescence efficiency remained unimproved. In 2002, a new structure was disclosed by A. B. Chwang, R. C. Kwong and J. J. Brown et al in Appl. Phys. Lett. 80, 725 (2002). By adjusting the co-deposition ratios of hole-transport material and electron-transport material, graded mixed layer devices consisting of multiple mixed layers of hole-transport material and electron-transport material with different mixing compositions were produced, wherein the compositions of mixed layers were gradually varied from 95%:5% (hole-transport material electron-transport material) near anode side to 10%:90% near cathode side. The component produced with such structure of prior art obtained reduced operation voltage, lengthened life span, but luminescence efficiency was lowered as compared with conventional abrupt hetero-junction. In fact, as the mixing composition needs to be adjusted during co-deposition, such structure and process substantially complicate the fabrication of OLED components, especially when luminescent doping needs to be carried out in the process. Further, such structure and fabrication process become more time- and material-consuming. Such structure complicates the fabrication process and may degrade the repeatability of the fabrication process. Furthermore, the structure of aforesaid component achieves only step-graded junction, and it is difficult to achieve truly graded junctions. Hence such component structure is more difficult and complicated to produce than conventional abrupt hetero-junction devices in terms of mass production.

In summary, the organic junction between plural organic layers is an essential portion of organic optoelectronic components in terms of effects on efficiency and life span. Although there were several methods in prior arts proposed for improving above mentioned performances, they have drawbacks in mass production due to its complexity of manufacturing process. Furthermore, the structure and fabrication process of prior art is incapable of obtaining enhanced luminescence efficiency and reduced operation voltage simultaneously. As one example, the graded junction with stepped variation fabricated by adjusting mixture ratios during deposition is capable of reducing operation voltage, but the luminescence efficiency was degraded, the complexity is substantially increased, and the fabrication repeatability may be reduced.

Therefore, a method for fabrication of graded organic junction of the invention is disclosed herein, when applied to fabrication of OLED, it can reduce operation voltage, enhance luminescence efficiency of OLED component, and further alleviate the complexity of fabrication process. Therefore the present invention provided improved productivity and performance of the organic optoelectronic components.

### SUMMARY OF THE INVENTION

The major objective of the invention is to disclose a fabrication method of graded organic junction to overcome drawbacks encountered in the fabrication of graded organic junction.

Another objective of the invention is to utilize graded organic junction fabrication method to produce OLED component with features of higher luminescence efficiency, reduced operation voltage and lengthened span life.

The major objective of the invention is to provide fabrication method of graded organic junction comprising steps:

adding an interfacial fusing layer between first organic layer and second organic layer; said interfacial fusing layer has its glass transition temperature lower than said first organic layer and said second organic layer;

annealing at temperature higher than the glass transition temperature of said interfacial fusing layer;

to form a graded organic junction; said fusing layers will cause interdiffusion to take place between said first organic layer and said second organic layer, resulting in said interface of said first organic layer and said second organic layer to become a graded junction; and

to monitor the formation process of graded junction by optical measurement device on real time basis.

Another objective of the invention is to provide OLEDs containing graded organic junction fabricated by the method of this invention. OLEDs fabricated by the method of the invention, comprising the stacked layers in sequence:

an anode;

a first organic layer, when applied with an external bias voltage to perform as the hole-transport layer;

an organic interfacial fusing layer, which can be annealed to let interdiffusion take place between organic layers and cause the interface between first organic layer and second organic layer to become a graded junction;

a second organic layer when applied with an external bias voltage to perform as the electron-transport layer; and

a cathode.

And when the electrons and holes transit in electron-transport layer and hole-transport layer towards each other, they will then produce excitons and luminescence as a result of carrier recombination.

The present invention will be readily apparent upon reading the following description of preferred exemplified embodiments of the invention and upon reference to the accompanying drawings.

### BRIEF DESCRIPTION OF DRAWINGS

FIG. 1 illustrates a schematic energy level diagram of a conventional OLED;

FIG. 2 illustrates a schematic diagram of an OLED containing graded junction of the invention:

(a) an initial state after completion of vacuum deposition process;

(b) after appropriate annealing to form graded junction;

FIG. 3 illustrates the comparison between conventional abrupt junction component and the graded junction component of the invention:

(a) component electroluminescence spectrum;

(b) component characteristics of current-voltage-brightness and electroluminescence quantum efficiency versus current;

(c) component characteristics of power efficiency versus voltage;

FIG. 4 illustrates the configuration of photoluminescence spectrum measurement for organic thin films of the invention;

(a) measurement configuration;

(b) photoluminescence spectrum of organic thin film after 3 minutes annealing;

FIG. 5 illustrates the comparison of conventional abrupt junction component and the graded junction component of the invention doped with luminescence material C545T;

(a) electroluminescence spectrum of the component doped with luminescence material C545T;

(b) component characteristics of current-voltage-brightness and quantum efficiency versus current;

(c) component characteristics of power efficiency versus voltage;

FIG. 6 illustrates the comparison of characteristics between conventional abrupt junction component and the graded junction component by utilizing TATE as hole-transport material and BCP as interfacial fusing material.

### DETAILED DESCRIPTION OF PREFERRED EMBODIMENTS

In general, a small molecule organic light emitting diode is fabricated through thermal vacuum deposition process to deposit thin films of amorphous organic materials sequentially onto a transparent glass substrate coated with ITO (Indium—Tin—Oxide) and followed by coating with a metal electrode (cathode) to produce the component. For purpose of performance and characteristics of component, OLED components normally consist of more than one organic layers of different properties, forming abrupt hetero-junction between different organic layers.

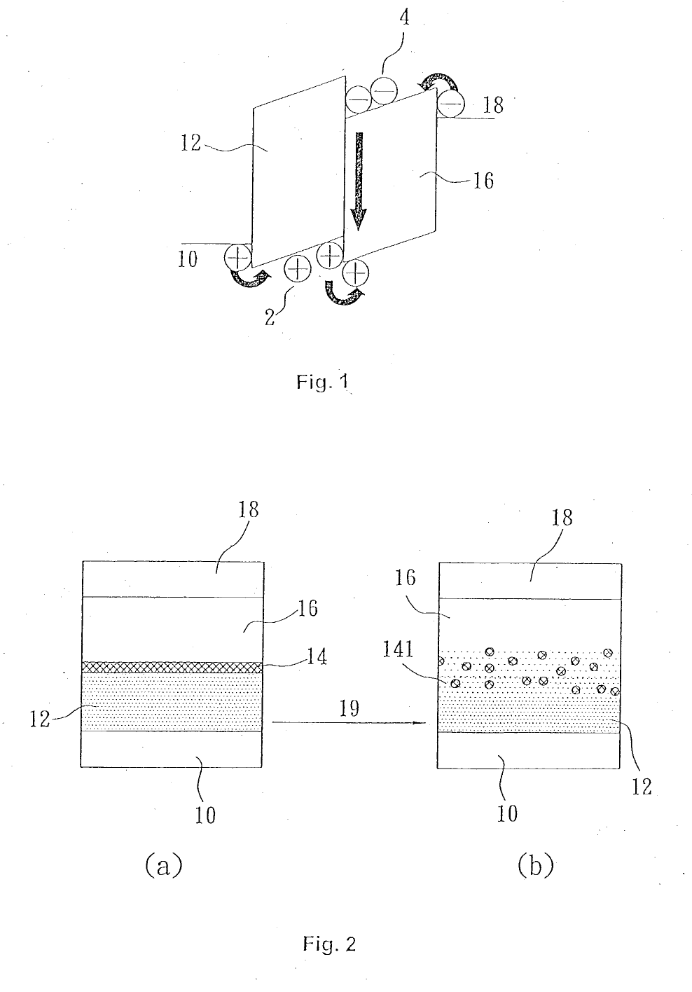

A typical double-layer abrupt junction OLED, for example, as illustrated in FIG. 1 with its material layers and schematic energy level diagram, mainly comprises an ITO anode 10, a hole-transport layer 12 (HTL), an electron-transport layer 16 (ETL), an metal cathode 18, holes 2 injected from ITO anode 12 into component, and electrons 4 injected from metal cathode 18 into component. Electrons 4 and holes 2 injected into the component transit in hole-transport layer 12 and electron-transport layer 16 respectively. When the electrons 4 and holes 2 transit toward each other, they will then produce exciton and luminescence as a result of carrier recombination. However, due to the unmatched energy levels and carrier transport characteristics of electron-transport layer 16 and hole-transport layer 12, abrupt hetero-junction will form an energy barrier to electrons 4 and holes 2 injected and hinder carriers from injecting to the neighboring organic layer, consequently resulting in higher operation voltage required. Further, the energy barrier will cause accumulation electrons 4 and holes 2 at neighborhood of the abrupt junction, and such space charges will cause the electric field in proximity abruptly to increase substantially, which will have adverse impact on the span life and luminescence efficiency of component.

The fabrication method disclosed by the present invention is to add an organic material with lower glass transition temperature between two different organic thin films with higher glass transition temperatures to act as an interfacial fusing layer for forming an organic graded junction. When annealing at a temperature higher than the glass transition temperature of said interfacial fusing layer, but lower than said two different organic thin film materials, said interfacial fusing layer will cause interdiffusion to take place between the organic materials, and a graded junction will be formed instead of conventional abrupt junction.

The fabrication method of graded organic junction of the present invention comprising steps:

adding an interfacial fusing layer between first organic layer and second organic layer, said interfacial fusing layer has its glass transition temperature lower than-said first organic layer and said second organic layer;

annealing at temperature higher than the glass transition temperature of said interfacial fusing layer;

to form a graded organic junction; and said fusing layers will cause interdiffusion to take place between said first organic layer and said second organic layer, resulting in said interface of said first organic layer and said second organic layer to become a graded junction; and

to monitor the formation process of graded junction by optical measurement device on real time basis.

The material selection for the invention is based on the principle: materials to form a graded junction have higher glass transition temperature than the material used for interfacial fusing layer. When annealing organic thin film to form graded organic junction, the temperature shall be higher than the glass transition temperature of interfacial fusing material but shall not cause substantial morphological transformation or degradation of other material layers. The graded junction of the invention was produced through interdiffusion, hence the variation of material composition of graded organic junction of the present invention can be more smooth than conventional stepped variation. Further, it is complicated in fabrication of graded junction with stepped variation of prior art for controlling compositions of co-deposited materials for each step. In contrast, the fabrication method of the present invention needs to deposit less material layers, followed by appropriate annealing to obtain a smooth graded organic junction, thus significantly alleviating compilation of fabrication process in prior art. The fabrication method of the present invention may be applicable to any organic hetero-junction to improve its component characteristics.

The material used for interfacial fusing layer is an organic material which is able to form solid thin film, whose thickness may be between 0.1 nm˜100 nm. The fabrication method of the present invention applied annealing temperature higher than glass transition temperature of organic interfacial fusing material but shall not cause substantial morphological change or degradation of said first organic layer and second organic layer to be formed in graded junction.

The graded organic junction fabricated by the method of the present invention is applicable to fabrication of OLED component comprising stacked layers in sequence:

an anode;

a first organic layer when applied with an external bias voltage to perform as hole-transport layer;

an organic interfacial fusing layer, which can be annealed to let interfusion take place between organic layers and cause the interface between first organic layer and second organic layer to become a graded junction;

a second organic layer when applied with an external bias voltage to perform as electron-transport layer; and

a cathode.

And when the electrons and holes transit in electron-transport layer and hole-transport layer towards each other, they will then produce exciton and luminescence as a result of carrier recombination.

When fabricating OLEDs by the method of the present invention, the glass transition temperature of interfacial fusing layer is lower than first organic layer (hole-transport layer) and second organic layer (electron-transport layer). The material is able to form solid thin film, whose thickness is between 0.1 nm˜100 nm. Further, the annealing temperature is higher than glass transition temperature of organic interfacial fusing material but shall not cause substantial morphological change or degradation of first organic layer and second organic layer to be formed in graded junction.

### EXAMPLE 1

### Fabrication of OLED Component

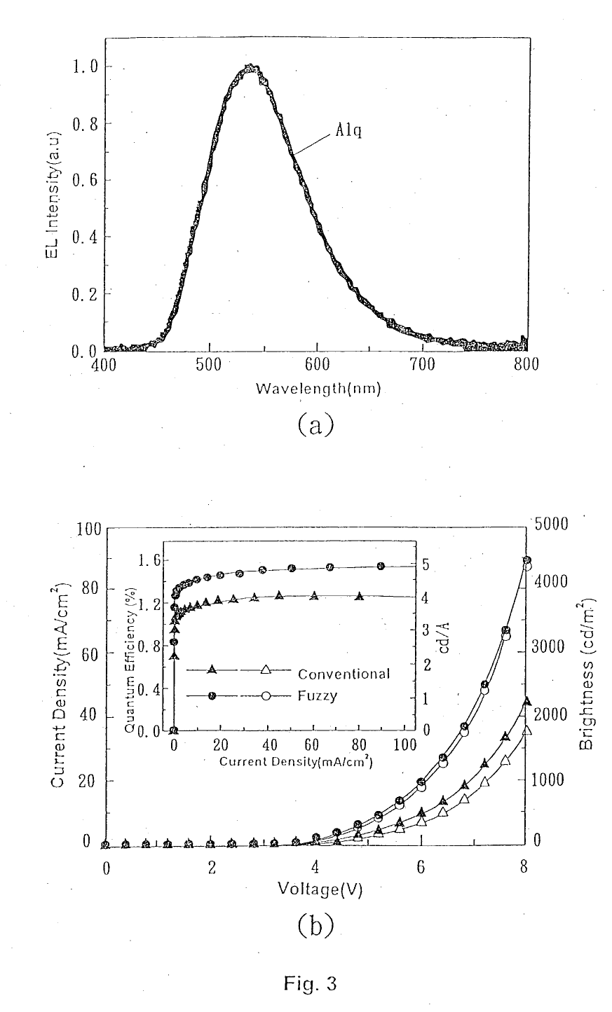

FIG. 2 illustrates the first embodiment of the structure of OLED with graded junction of the invention which comprises an ITO anode 10, a hole-transport layer 12, an organic interfacial fusing layer 14, an electron-transport layer 17 and a metal cathode 18. FIG. 2a illustrates the component structure after completion of vacuum deposition process. By appropriately annealing (19), the organic interfacial fusing layer 14 causes interdiffusion between materials and form an graded organic junction 141 as shown in FIG. 2b. In one embodiment the materials used are selected as follows:

hole injection material: polyethylene dioxythiophene/polystyrene sulphonate (PEDT:PSS), as shown in chemical formula (1);

hole-transport material: α-naphthylphenylbiphenyl diamine (α-NPD, Tg˜100° C.), as shown in chemical formula (2);

organic interfacial fusing material: bis-4, 4′-[(diphenylmethylsilyl) vinyl] biphenyl (DPSVB, Tg˜30° C.), as shown in chemical formula (3), and;

electron-transport material: tris-(8-hydroxyquinoline) aluminum (Alq, Tg˜170° C.), as shown in chemical formula (4).

The materials are set forth for example, materials with similar properties may be used to fabricate the same.

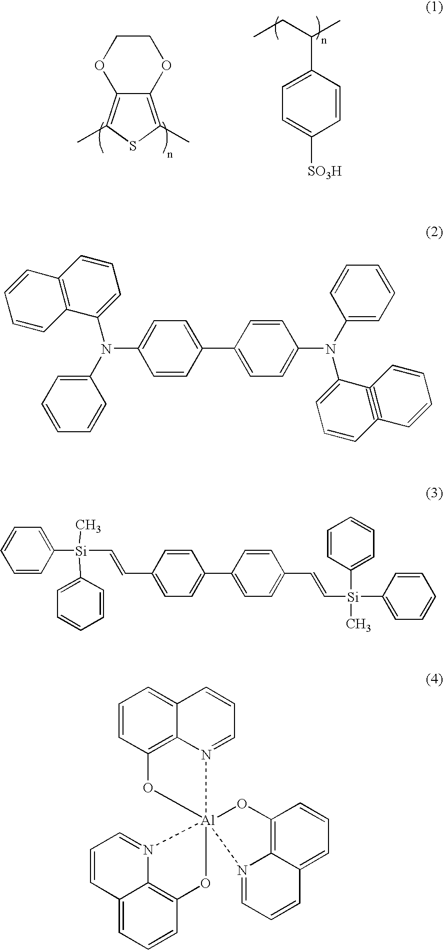

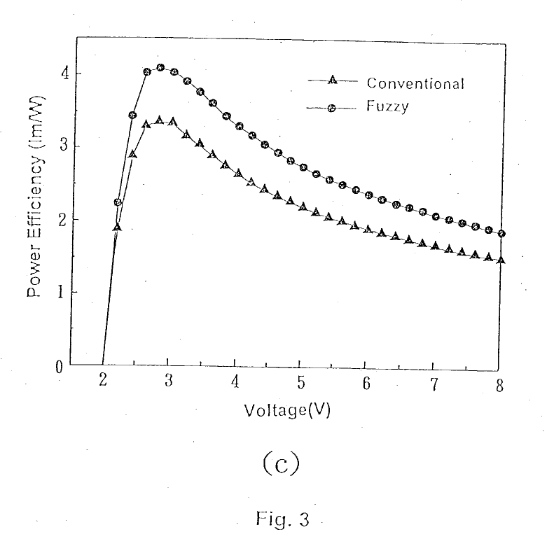

FIG. 3 compares the characteristics of conventional abrupt hetero-junction component and the graded-junction component of the present invention.

structure of conventional abrupt junction component: ITO/PEDT:PSS(30 nm)/α-NPD(40 nm)/Alq(60 nm)/LiF(0.5 nm)/Al(150 nm);

structure of graded junction component: ITO PEDT:PSS(30 nm)/α-NPD(40 nm)/DPSVB(1 nm)/Alq(60 nm)/LiF(0.5 nm)/Al(150 nm); the graded-junction devices underwent annealing at 80° C. for 3 minutes after device deposition.

FIG. 3a shows green electroluminescence device from Alq molecule from either the conventional abrupt junction component or the graded junction device. Therefore, it shows that although graded interfacial fusing layer was added in graded junction component, it does not affect the component electroluminescence spectra. FIG. 3b shows component characteristics of current-voltage-brightness and electroluminescence quantum efficiency versus current (solid symbol: current vs voltage; open symbol: brightness vs voltage). FIG. 3b shows that graded junction component (indicated by circle symbol) is capable of injecting more current along with higher electroluminescence quantum efficiency than conventional abrupt junction component (indicated by upward triangle symbol) under same operation voltage. It is shown in FIG. 3c, a power efficiency vs component voltage curve, that the power efficiency of graded organic junction component is also higher than conventional abrupt junction component.

### EXAMPLE 2

### Monitoring the Formation of Graded Organic Junction

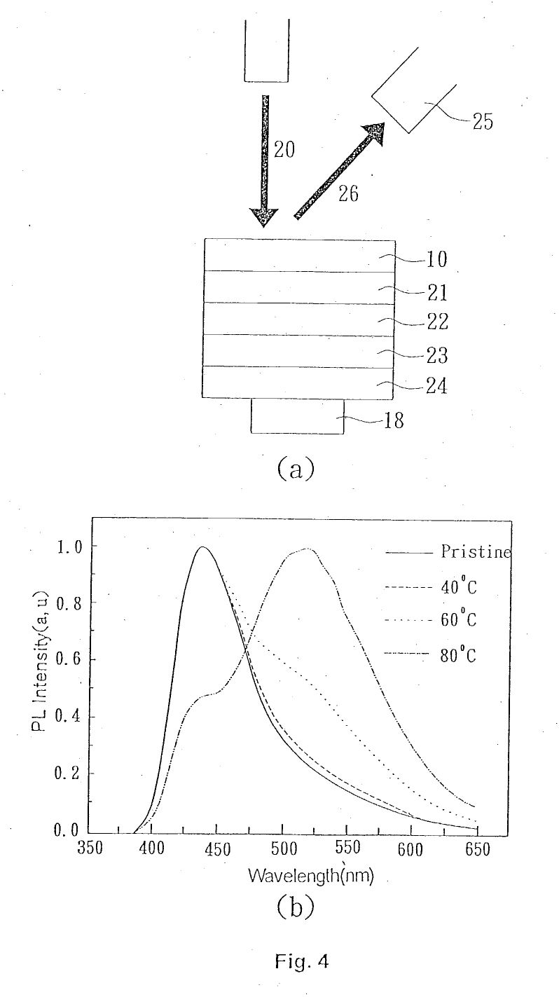

In order to verify the abrupt junction being transformed into organic graded junction and to monitor the transformation of graded junction, one may measure photoluminescence spectrum of the organic thin films within the component. The main elements of measurement device consisting essentially of an excitation light source and an optical detector connected to spectrum analyzer for analyzing photoluminescence spectra FIG. 4 illustrates the configuration of photoluminescence spectra measurement for organic thin films within the component. The component from top to bottom comprising ITO 10, hole injection material 21, hole-transport material 22, organic interfacial fusing material 23, electron-transport material 24 and metal cathode 18, as shown in FIG. 4a. In the experiment, the excitation light source 20 is incident through the transparent substrate and ITO 10. The wavelength of the excitation light source 20 is selected to be easier for hole-transport material 22 to absorb and more difficult for electron-transport material 24 to absorb. In this embodiment example, hole-transport material 22 is α-NPD and electron-transport material 24 is Alq as indicated in chemical formula 2 and 4 respectively. The whole device structure is: ITO PEDT:PSS(30 nm)/α-NPD(60 nm)/DPSVB(15 nm)/Alq(30 nm)/LiF(0.5 nm)/Al(150 nm). Therefore, the wavelength of excitation light source 20 being selected was 365 nm, and the light detector 25 was positioned on ITO anode 10 side for receiving the photoluminescence 26 emitted from organic films, and detector 25 was connected to spectrum analyzer for analyzing photoluminescence spectra. With reference to FIG. 4b, it shows photoluminescence spectra of organic films within the component containing graded organic junction, which was heated 3 minutes at varied temperatures after device deposition. The photoluminescence spectrum of unheated component is similar to blue light emitted by α-NPD. As the annealing temperature increases, the light emission from α-NPD decreases and the green emission from Alq increases. It indicated that when organic thin film was not heated, Due to the existence of an organic interfacial fusing material 23 between hole-transport material 22 α-NPD and electron-transport material 24 Alq, the distance between α-NPD and Alq is larger, and the energy transfer capability among molecules is very low, thus most energy of excitation light source 20 was absorbed by α-NPD, followed by direct emission from α-NPD layer. However, as the annealing temperature increases, the interdiffusion induced by organic interfacial fusing material 23 becomes more significant and causes molecules of α-NPD and Alq initially on two sides of organic interfacial fusing material to mix. As temperature rises the degree of mixing becomes more significant, resulting more energy transfer from excited α-NPD molecules to Alq molecules, therefore along with increased green emission. Therefore, during the annealing process, one is capable of monitoring and controlling the status of graded organic junction within component on real time basis by monitoring the variation of photoluminescence spectra.

### EXAMPLE 3

### Fabrication of Light Emitting Component With Doping Material

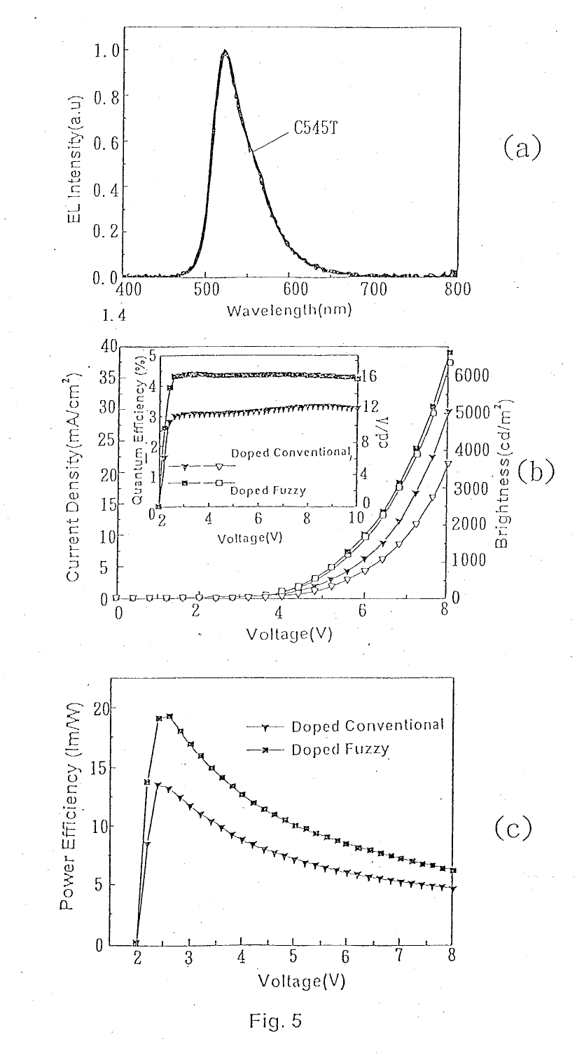

In order to enhance luminous efficiency, the luminescence layer of light-emitting component may be doped with luminescence doping material. FIG. 5 compares components characteristics between conventional abrupt junction component and the graded junction component of the present invention, both doped with luminescence material C545T as shown in formula 5.

The structure of conventional abrupt junction component is:

ITO/PEDT:PSS(30 nm)/α-NPD(40 nm)/Alq:C545T(1 wt. %)(30 nm)/Alq(30 nm)/LiF(0.5 nm)/Al(150 nm);

the structure of graded junction component is:

ITO/PEDT:PSS(30 nm)/α-NPD(40 nm)/DPSVB(1 nm)/Alq:C545T(1 wt. %)(30 nm)/Alq(30 nm)/LiF(0.5 nm)/Al(150 nm).

FIG. 5a illustrates the electroluminescence spectrum of the component doped with luminescence material C545T; FIG. 5b illustrates component characteristics of current-voltage-brightness and luminescence quantum efficiency versus current (the solid symbol current vs voltage, open symbol: brightness vs voltage). As shown in the FIG. 5b, the graded junction component (indicated by square symbol) has larger injection current under same operation voltage, and the luminescence efficiency of graded junction component reaches ˜4.5% (under 3V operation voltage), which is greater than ˜3.4% (under 8.5V operation voltage) of conventional abrupt junction component (indicated by downward triangle). As for component energy efficiency, it can be seen from FIG. 5c that the energy efficiency of graded-junction component can reach max. 20 lm/W, and 14 lm/W at the brightness of 100 cd/m², obviously greater than max. 13.5 lm/W and 8 lm/W at brightness 100 cd/m² of conventional abrupt junction component.

### EXAMPLE 4

### Thermal Stability Test for Graded Organic Junction

Because in the previous embodiments the glass transition temperature Tg of interfacial fusing material DPSVB is low, hence a thermal stability test was performed for the graded-junction components in previous two embodiments with 80° C. heating for 60 minutes. It was found that the characteristics of component, after 80° C. heating for 60 minutes, hardly changed in comparing to the components previously only undergoing 80° C. heating for 3 minutes. It indicates that interdiffusion induced by interfacial fusing layer may ultimately reach a self-limiting state.

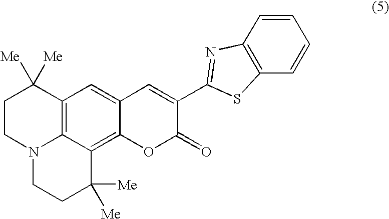

### EXAMPLE 5

### Using Higher Tg Material to Fabricate Light Emitting Component

Recent research reports indicated that OLED life span may be lengthened by using organic material with higher Tg. One may choose the higher-Tg materials to fabricate graded-junction OLED. Still the material choice may follow the principle: material to form a graded junction shall have higher glass transition temperature than the material used for interfacial fusing layer. For example, in this example a hole-transport material having the chemical structure: N,N′-diphenyl-N,N′-bis (4′-(N,N-bis (naphtha-1-yl)-amino)-biphenyl-4yl)-benzidine (a triarylamine tetramer (TATE, Tg˜150° c.) as shown in formula 6) is used to replace α-NPD in previous embodiment. The material chosen for interfacial fusing material is:

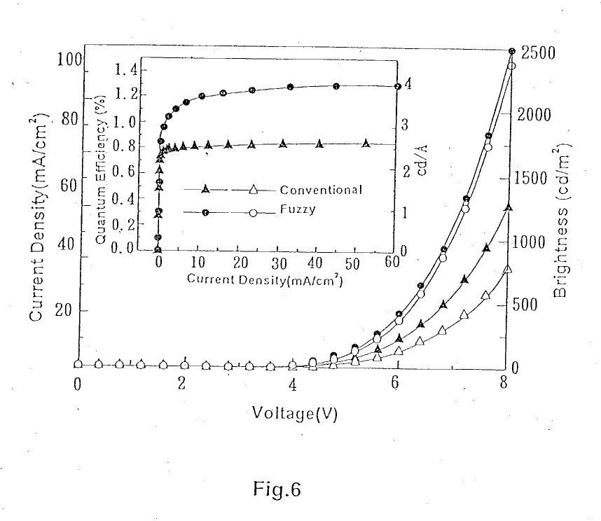

2, 9-dimethyl-4, 7-diphenyl-1, 10-phenanthroline (BCP,Tg˜80° C.) (as shown in formula 7) to replace the interfacial fusing material DPSVB in previous embodiments. Conventional abrupt junction component with the structure: ITO/PEDT:PSS(30 nm)/TATE(40 nm)/Alq(60 nm)/LiF(0.5 nm)/Al(150 nm), and graded junction device with the structure of: ITO/PEDT:PSS(30 nm)/TATE(40 nm)/BCP(5 nm)/Alq(60 nm)/LiF(0.5 nm)/Al(150 nm), were fabricated. The graded-junction components were heated with 120° C. for 3 minutes after deposition. This annealing condition complies with aforesaid principle: when annealing organic thin film to form graded organic junction, the temperature shall be higher than the glass transition temperature of interfacial fusing material but shall not cause substantial morphological change and degradation of the other material layers. FIG. 6 shows comparison of these two components (solid symbol: current vs voltage; open symbol: brightness vs voltage). It is evident that graded junction component (indicated by circle symbol) of the present invention is capable of injecting more current than conventional abrupt junction component (indicated by upward triangle symbol) under same operation voltage. The embodiment shows that graded junction of the present invention can be generally utilized in the field of OLED component fabrication for various materials combinations, giving similar benefits to device performance.

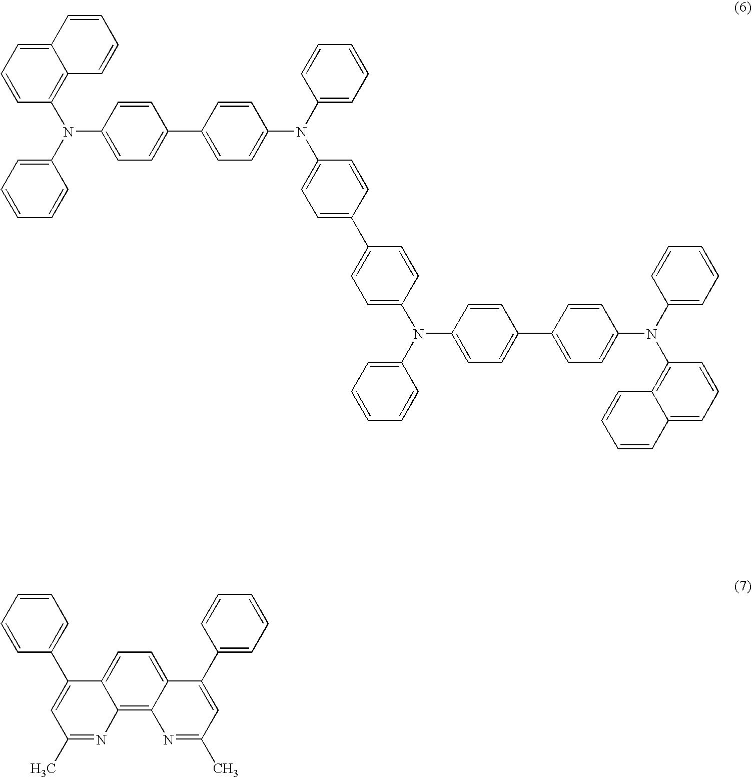

From the above descriptions, the fabrication method of graded junction of the present invention is by appropriate annealing organic materials having different phase transition temperature to induce interdiffusion between materials to form graded junction. It may be generally applied in combinations of organic materials in compliance with the principle: annealing temperature shall be higher than the glass transition temperature of interfacial fusing material but shall not cause substantial morphological change and degradation of the other material layers. The graded organic junction thus fabricated is not limited to the junction between the electron-transport material and the hole-transport material of aforesaid OLED, but may be also applicable, in an appropriate manner, to other junctions in OLEDs with more organic layers. The present invention may also be applied to other organic optoelctronic devices containing organic junctions, such as organic solar cells, organic photoresponsive component etc., to improve performances of components.

What is claimed is:

1. A fabrication method of graded organic junction comprising steps:
adding an interfacial fusing layer between first organic layer and second organic layer; said interfacial fusing layer has its glass transition temperature lower than said first organic layer and said second organic layer;
annealing at temperature higher than the glass transition temperature of said interfacial fusing layer;
forming the graded organic junction; by annealing said fusing layers will cause interdiffusion to take place between said first organic layer and said second organic layer, resulting in said interface of said first organic layer and said second organic layer to become a graded junction.

2. A fabrication method of graded junction as set forth in claim 1, wherein the variation of photoluminescence spectra may be monitored, while annealing said graded organic junction, by use of optical measurement device.

3. A fabrication method of graded junction as set forth in claim 2, wherein the main elements of said optical measurement device consisting essentially of an excitation light source and an optical detector connected to spectrum analyzer for analyzing photoluminescence spectra.

4. A fabrication method of graded junction as set forth in claim 1, wherein the material used for interfacial fusing layer is an organic material which is able to form solid thin film.

5. A fabrication method of graded junction as set forth in claim 1, wherein the thickness of organic interfacial fusing layer is between 0.1 nm˜100 nm.

6. A fabrication method of graded junction as set forth in claim 1, wherein said annealing temperature is higher than the glass transition temperature of organic interfacial fusing layer but shall not cause substantial morphological change or degradation of said first organic layer and said second organic layer to be formed in graded junction.

7. An organic light emitting device (OLED) component containing the graded organic junction produced by the fabrication method set forth in claim 1, said component comprising stacked layers in sequence:
an anode;
a first organic layer when applied with an external bias voltage to perform as hole-transport layer;
an organic interfacial fusing layer, when annealing, will induce interfusion between organic layers, and cause the interface of first organic layer and second organic layer to become a graded junction;
a second organic layer when applied with an external bias voltage to perform as electron-transport layer; and
a cathode.

8. An organic light emitting device (OLED) as set forth in claim 7, wherein the variation of photoluminescence spectra may be monitored, while annealing said graded organic junction, by use of optical measurement device.

9. An organic light emitting device (OLED) as set forth in claim 8, wherein the main elements of said optical measurement device consisting of an excitation light source and an optical detector connected to spectrum analyzer for analyzing photoluminescence spectra.

10. An organic light emitting device (OLED) as set forth in claim 7, wherein the glass transition temperature of said organic interfacial fusing layer is lower than the glass transition temperature of said first organic layer and said second organic layer.

11. An organic light emitting device (OLED) as set forth in claim 7, wherein the material used for interfacial fusing layer is an organic material which is able to form solid thin film.

12. An organic light emitting device (OLED) as set forth in claim 7, wherein the thickness of organic interfacial fusing layer is between 0.1 nm˜100 nm.

13. An organic light emitting device (OLED) as set forth in claim 7, wherein said annealing temperature is higher than glass transition temperature of organic interfacial fusing material but shall not cause substantial morphological change or degradation of said first organic layer and said second organic layer to be formed in graded junction.
